(19) United States
(12) Patent Application Publication
(10) Pub. No.: US 2008/0109706 A1
(43) Pub. Date: May 8, 2008

(54) ERROR CORRECTION METHOD AND APPARATUS FOR OPTICAL INFORMATION STORAGE MEDIUM RECORDING/REPRODUCING APPARATUS

(75) Inventor: Yong-suk AHN, Gunpo-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/692,617

(22) Filed: Mar. 28, 2007

(30) Foreign Application Priority Data
Oct. 24, 2006 (KR) 2006-103611

(51) Int. Cl. G11C 29/00

(52) U.S. Cl. 714/768

(57) ABSTRACT

An error correction method and apparatus for use in an optical information storage medium recording/reproducing apparatus, in which an error data value is detected from the original data value stored in an external memory unit and a corrected data value for the error data value is updated to the external memory unit. The error correction method includes receiving position information about positions of a plurality of error data values detected by an error checking and correction (ECC) block and error data values for a plurality of codewords in a column direction, comparing the positions of the error data values of the codewords, and when the plurality of error data values have the same position, updating corrected data values for the error data values to the external memory unit using error values of the error data values at the same time.

### CROSS-REFERENCE TO RELATED APPLICATIONS

This application claims the benefit of Korean Patent Application No. 2006-103611, filed on Oct. 24, 2006 in the Korean Intellectual Property Office, the disclosure of which is incorporated herein by reference.

### BACKGROUND OF THE INVENTION

1. Field of the Invention

Aspects of the present invention relate to a method and apparatus for error correction and updating for use in an optical information storage medium recording/reproducing apparatus, and more particularly, to a method of and apparatus for performing error checking and correction (ECC) on a data memory that stores sector data of an optical disc at high speed and updating corrected data to an external memory.

2. Description of the Related Art

Optical disc recording/reproducing apparatuses are used to record/reproduce multimedia data such as audio data, video data, and digital data to/from optical discs such as compact discs (CDs) or digital versatile discs (DVDs). Such apparatuses have high recording capacities and short access times.

A conventional decoding apparatus for an optical disc recording/reproducing apparatus includes an error checking and correction (ECC) processing unit to perform ECC on errors when decoding sector data stored in a data memory. The ECC processing unit reads data in an ECC block from the data memory, performs ECC on the data, and stores corrected data in an external synchronous dynamic random access memory (SDRAM).

FIG. 1A illustrates an ECC block used in an optical disc recording/reproducing apparatus. The ECC block includes 192 rows, each of which is composed of 182 bytes. The ECC block includes an information field composed of 176 rows, each of which is composed of 172 bytes, an inner parity (IP) composed of 10 bytes for error correction with respect to data in the information field, and an outer parity (OP) composed of 16 rows. In FIG. 1A, a indicates a codeword composed of data in the row direction of the ECC block and b indicates a codeword composed of data in the column direction of the ECC block. The data in the ECC block has a size of 1 byte and is composed of 0^{th} through 181^{st} columns, in which even columns consist of upper bytes and odd columns consist of lower bytes.

FIG. 1B illustrates the structure of data stored in an external SDRAM. As illustrated in FIG. 1B, in the external SDRAM, 91 error-corrected address data is composed of 96 rows, in which single address data is composed of 2 bytes. Thus, an upper 1 byte and an adjacent lower 1 byte are stored by the ECC block in single address data in the external SDRAM. The corrected data is stored by the ECC block in the external SDRAM through a writing operation, thereby completing data updating.

In other words, the ECC block reads the original data having an error from the external SDRAM, detects the position of data having the error, corrects the error, and updates the data position and the corrected data to the external SDRAM. The ECC block repeats the process of reading the original data from the external SDRAM, correcting an error, and updating the external SDRAM, until all data stored in the optical disc has been corrected.

FIG. 2 is a view explaining an error correction method for use in an optical disc recording/reproducing apparatus according to the prior art. According to the prior art, after IP error correction is performed on codewords one by one in the row direction of an ECC block, an error of IP data and the position of the error are recognized to correct the error and to update the external SDRAM accordingly.

If more than a predetermined number of errors are detected during the IP error correction, the IP error correction terminates, OP error correction is performed on codewords one by one in the column direction, and the corrected data is stored in the external SDRAM. In general, as illustrated in FIG. 1A, in the case of the ECC block of 182×192, IP error correction terminates if at least 6 errors are detected in the row direction and OP error correction terminates if at least 9 errors are detected in the column direction.

In FIG. 2, 13 errors, error (1) through error (13), exist in the ECC block, In addition, (a) indicates a sequential increasing direction of addresses in an SDRAM, (b) and (c) indicate codewords composed of data in the column direction, respectively, and (d) indicates a codeword composed of data in the row direction.

Since the external SDRAM updates data in units of 2 bytes along the direction (a), the external SDRAM reads or writes 2 bytes, including an upper byte and a lower byte, during a single read or write operation. Since error correction is performed byte-by-byte, the upper byte, the lower byte, or 2 bytes including the upper byte and the lower byte may be updated to the external SDRAM during a single update operation.

To update the codeword (d) in the row direction to the external SDRAM, a total of 2 bytes including the upper byte and the lower byte can be updated in singe address data of the external SDRAM. For example, in the case of error (6), only the upper byte is error-corrected and updated to the external SDRAM. In the case of errors (11) and (12), the upper byte and the lower byte are error-corrected and updated to the external SDRAM. In the case of error (13), the lower byte is error-corrected and updated to the external SDRAM.

To update the codewords (b) and (c) in the column direction in the external SDRAM, for updates with respect to an even-numbered codeword like the codeword (b), only the upper byte of the even-numbered codeword is updated. For updates with respect to an odd codeword like the codeword (c), only the lower byte of the odd codeword is updated. Thus, when the errors (1) through (6) of the codeword (b) corresponding to upper bytes are error-corrected and then updated, errors (7) through (10) corresponding to lower bytes maintain their existing values. Similarly, when errors (7) through (10) of the codeword (c) corresponding to lower bytes are error-corrected and then updated, errors (1) through (6) corresponding to upper bytes maintain their existing values.

Therefore, 6 write operations are performed in the external SDRAM due to 6 errors during the updating of the codeword (b) and 4 write operations are performed in the external SDRAM due to 4 errors during the updating of the codeword (c).

Although the errors (3) and (8) are included in the same address and the errors (5) and (9) are included in the same address, they require a total of 4 write operations. As such, the time required to update the external SDRAM increases in proportion to the number of errors, thereby hindering rapid updating.

### SUMMARY OF THE INVENTION

Aspects of the present invention provide an error correction method for use in an optical disc recording/reproducing apparatus, in which error data is corrected and corrected data is stored in an external synchronous dynamic random access memory (SDRAM) at high speed.

According to one aspect of the present invention, there is provided an error correction method for use in an optical information storage medium recording/reproducing apparatus, in which an error data value is detected from original data value obtained from an optical information storage medium and stored in an external memory unit and a corrected data value for the error data value is updated to the external memory unit. The error correction method includes receiving position information about the positions of a plurality of error data values detected by an error checking and correction (ECC) block and the error data values for a plurality of codewords oriented in a column direction, comparing the positions of the error data values of the codewords, and when the plurality of error data values have the same position, updating the external memory unit with corrected data values for the error data values simultaneously using error values of the error data values.

According to another aspect of the present invention, the comparison of the positions may include comparing row-direction positions of the error data values of the codewords.

According to another aspect of the present invention, the error correction method may further include, when the error data values compared with each other do not have the same row-direction position, sequentially updating the external memory unit with the corrected data values for the error data values using error values of the error data values.

According to another aspect of the present invention, the corrected data values may be stored at the same address of the external memory unit.

According to another aspect of the present invention, the ECC block may receive the original data value stored in the external memory unit and detect the position information and the error value of the error data value.

According to another aspect of the present invention, an operation may be performed on the original data value and the error value to generate the corrected data values and to update the external memory unit with the corrected data values.

According to another aspect of the present invention, there is provided an error correction apparatus for use in an optical disc recording/reproducing apparatus, the error correction apparatus including a codeword buffer unit and a control unit. The codeword buffer unit receives position information about the positions of a plurality of error data values detected by an error checking and correction (ECC) block and obtained from an optical information storage medium and the error data values for a plurality of codewords oriented in the column direction. The control unit compares the positions of the error data values of the codewords and updates the external memory unit with corrected data values for the error data values using error values of the error data values simultaneously when the plurality of error data values have the same position.

According to another aspect of the present invention, the control unit may compare row-direction positions of the error data values of the codewords.

According to another aspect of the present invention, when the error data values compared with each other do not have the same row-direction position, corrected data values for the error data values may be updated to the external memory unit sequentially using error values of the error data values.

According to another aspect of the present invention, the control unit may include a read buffer unit to receive and store the original data value stored in the external memory unit.

According to another aspect of the present invention, the control unit may further include an error data comparison unit to compare the error data values of the codewords and a corrected data generation unit to generate the corrected data value by performing an operation on the original data value and the error value and to update the external memory unit with the corrected data value according to the comparison result of the error data comparison unit.

According to another aspect of the present invention, the control unit may further include an address generation unit to set an address of the external memory unit in which the corrected data value is to be stored, using the position information of the error data value and the comparison result of the error data comparison unit.

According to another aspect of the present invention, the ECC block may receive the original data value stored in the external memory unit and detect the position information and the error value of the error data value.

According to another aspect of the present invention, there is provided an error correction system for use in an optical information storage medium recording/reproducing apparatus, the error correction system including an external memory unit, an error checking and correction (ECC) block, and an error update unit. The external memory unit stores an original data value obtained from an optical information storage medium. The ECC block receives the original data value stored in the external memory unit, detects an error data value from the original data value, and generates position information about the position of the error data value to be corrected and an error value of the error corrected value. The error update unit receives position information about the positions of a plurality of error data values detected by the ECC block and the error data values for a plurality of codewords oriented in the column direction, compares the positions of the error data values of the codewords, and updates the external memory unit with corrected data values for the error data values using error values of the error data values simultaneously when the plurality of error data values have the same position.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A illustrates an error checking and correction (ECC) block used in optical disc recording/reproducing apparatus;

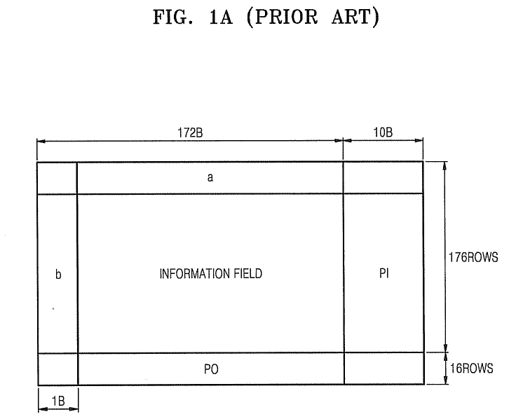

FIG. 1B illustrates the structure of data stored in an external synchronous dynamic random access memory (SDRAM);

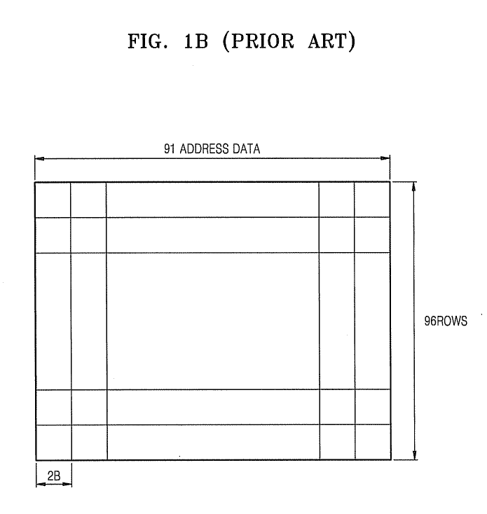

FIG. 2 is a view for explaining a conventional error correction method for use in an optical disc recording/reproducing apparatus;

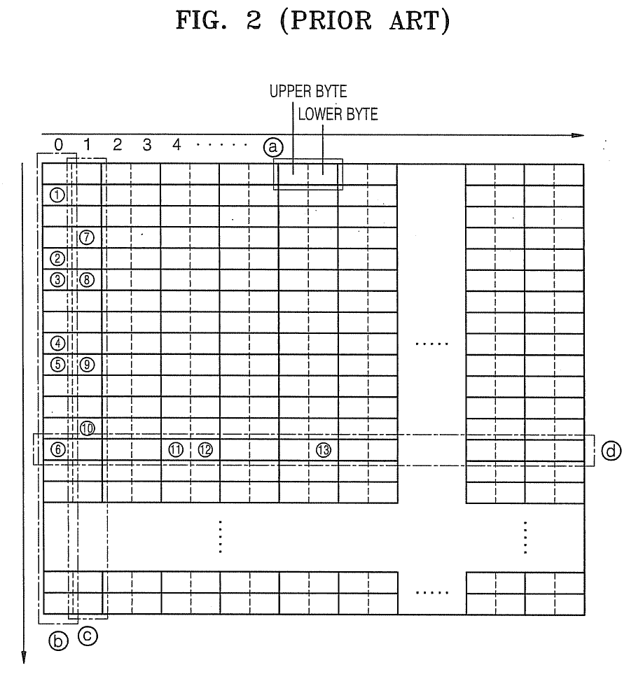

FIG. 3 is a block diagram of an error correction system for use in an optical information storage medium reproducing/recording apparatus according to an embodiment of the present invention;

FIG. 4 is a flowchart illustrating an error correction method performed in an error update unit of the system of FIG. 3 according to an embodiment of the present invention; and

FIG. 5 illustrates an example of an error correction method for use in an optical information storage medium reproducing/recording apparatus according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

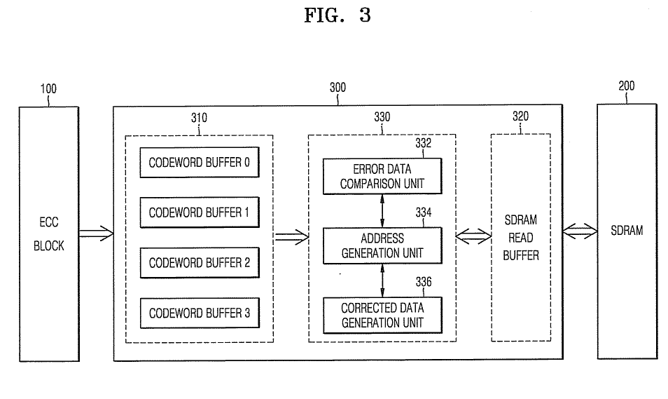

FIG. 3 is a block diagram of an error correction system for use in an optical information storage medium reproducing/recording apparatus according to an embodiment of the present invention. The error correction system includes an error checking and correction (ECC) block 100 to correct error data, an external synchronous dynamic random access memory (SDRAM) 200 to store corrected data, and an error update unit 300 to deliver the corrected data to the external SDRAM 200 at high speed. However, according to other aspects of the invention, various storage media capable of storing data, instead of SDRAM, may be updated with corrected data.

The ECC block 100 receives original data stored in the external SDRAM 200, detects errors in the original data, and generates position information of the errors to be corrected and corrected data. The external SDRAM 200 stores the original data obtained from an optical information storage medium and is updated by reading the corrected data from the error update unit 300.

In other words, the ECC block 100 reads the original data having an error from the external SDRAM 200, recognizes the position of the error, corrects the error position, and delivers error position information and the data to be corrected to the error update unit 300. The error update unit 300 corrects the data and updates the corrected data to the external SDRAM 200 at high speed.

The error update unit 300 according to an embodiment of the present invention will be described in detail. As illustrated in FIG. 3, the error update unit 300 includes a codeword buffer unit 310, a control unit 330, and an SDRAM read buffer 320.

The codeword buffer unit 310 includes four codeword buffers (codeword buffer 0, codeword buffer 1, codeword buffer 2, and codeword buffer 3) and receives and stores position information of error data to be corrected and the error data to be corrected from the ECC block 100. Each of the four codeword buffers can store information about one codeword. Thus, four codewords are sequentially stored in the four codeword buffers and are updated to the external SDRAM 200 in a manner that a first stored codeword is first updated. In other words, after error data stored in codeword buffer 0 through codeword buffer 3 are corrected and updated to the external SDRAM 200, information about a next four codewords is stored. Other aspects of the present invention may include more codeword buffers.

The SDRAM read buffer 320 reads and stores the original data stored in the external SDRAM 200 before error correction and updating.

The control unit 330 includes an error data comparison unit 332, an address generation unit 334, and a corrected data generation unit 336. The error data comparison unit 332 is used to update a codeword in the column direction and compares error position information of codewords included in two codeword buffers to determine whether the error position information of the codewords are identical to each other. The address generation unit 334 reads position information of error data stored in the codeword buffer unit 310 and sets an address of the external SDRAM 200 in which corrected data is to be stored based on a result from the error data comparison unit 332. The corrected data generation unit 336 receives position information stored in the codeword buffer unit 310, generates corrected data by performing an exclusive OR (XOR) operation (or other operation, according to other aspects of the invention) on the original data from the external SDRAM 200 stored in the SDRAM read buffer 320 and the error data stored in the codeword buffer unit 310, and updates the corrected data to the external SDRAM 200. If the positions of the error data included in the two codewords are identical to each other, the error-corrected data are updated to the external SDRAM 200 at the same time.

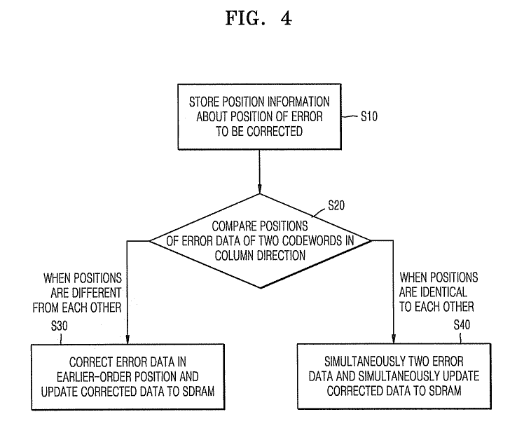

A method of updating a codeword in the column direction at high speed will be described. FIG. 4 is a flowchart illustrating an error correction technique that may be performed in the error update unit 300 according to an embodiment of the present invention. First, in operation S10 an error to be corrected and the error's position, input from the ECC block 100, are stored for each codeword in the codeword buffer unit 310.

In operation S20, the error data comparison unit 332 compares the positions of errors in two column-direction codewords having the same address in the external SDRAM 200. The position of an error in an even-numbered codeword corresponding to upper bytes, stored in the codeword buffer 0, is compared with the position of an error in an odd-numbered codeword corresponding to lower bytes, stored in the codeword buffer 1. Similarly, the position of an error in an even codeword corresponding to upper bytes, stored in codeword buffer 2, is compared with the position of an error in an odd codeword corresponding to lower bytes, stored in codeword buffer 3. If the positions of the errors of the even codeword and the errors of the odd codeword are different from each other, the corrected data generation unit 336 generates error-corrected data for the error data in the earlier-order position to update the error-corrected data to the external SDRAM 200 in operation S30. According to other aspects of the invention, operation S30 may involve comparison of three or more codewords.

The error in the earlier-order position indicates an error corrected before the other error when updating the row direction. Thus, if the error in the even codeword is in the earlier-order position than the error in the odd codeword, the error data of the even codeword corresponding to upper bytes is corrected and updated and the error in the odd codeword corresponding to lower bytes is maintained. However, if the error in the odd codeword is in the earlier-order position than the error in the even codeword, the error in the odd codeword corresponding to lower bytes is corrected and updated and the error in the even codeword corresponding to upper bytes is maintained.

If the positions of the error in the even-numbered codeword and the odd-numbered codeword are identical, the corrected data generation unit 336 simultaneously generates corrected data for the error data of upper bytes and lower bytes and simultaneously updates the corrected data to the external SDRAM 200 in operation S40. In other words, errors in two codewords included in the same address are corrected and updated at the same time, thereby reducing the time required for unnecessary write/read operations to/from the external SDRAM 200 and thus allowing for rapid update.

Once error data stored in codeword buffer 0 through codeword buffer 3 are corrected and updated to the external SDRAM 200, error correction and update to the external SDRAM 200 are performed for the next four codewords in the same way as described above.

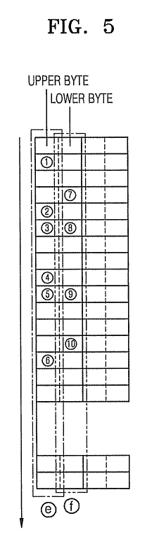

A detailed example using the error correction technique of FIG. 4 will be described with reference to FIG. 5. FIG. 5 illustrates an example of an error correction method for use in an optical information storage medium reproducing/recording apparatus according to an embodiment of the present invention. Codewords (e) and (f) are codewords in the column direction and their data are included in the same address of an external SDRAM 200. The codeword (e) includes data corresponding to the upper bytes and the codeword (f) includes data corresponding to the lower bytes. Ten errors, error (1) through error (10), are distributed throughout the codeword (e) and the codeword (f).

When errors to be corrected and their corresponding positions are stored for each codeword in the codeword buffer unit 310, the positions of 6 errors of the codeword (e) and the 6 errors (1) through (6) are stored in codeword buffer 0. Similarly, the positions of 4 errors of the codeword (f) and the 4 errors (7) through (10) are stored in codeword buffer 1.

The error data comparison unit 332 compares the position of error (1) of codeword buffer 0 with the position of error (7) of codeword buffer 1. Since error (1) is in the earlier position, the corrected data generation unit 336 corrects the error (1) and updates corrected data to the external SDRAM 200. The address generation unit 334 sets an address of the external SDRAM 200 in which the corrected data is to be updated and stored.

The error data comparison unit 332 then compares the position of error (2) of codeword buffer 0 with the position of error (7) of codeword buffer 1. Since error (7) is in the earlier position, the corrected data generation unit 336 corrects the error (7) in the earlier-order position and updates corrected data to the external SDRAM 200.

The error data comparison unit 332 compares the position of error (2) of codeword buffer 0 with the position of error (8) of codeword buffer 1. The corrected data generation unit 336 corrects the error data (2) in the earlier-order position and updates corrected data to the external SDRAM 200.

The error data comparison unit 332 compares the position of error (3) of codeword buffer 0 with the position of error (8) of codeword buffer 1. Since the positions of the error (3) and the error (8) are identical to each other, the corrected data generation unit 336 simultaneously corrects the error (3) and the error (8) and simultaneously updates corrected data to the external SDRAM 200. The operations described above are applied to the remaining errors in a similar fashion and thus a detailed description thereof will not be provided.

Thus, according to aspects of the present invention, corrected data for the error (3) and the error (8) included in the same address can be updated to the external SDRAM 200 simultaneously and corrected data for the error (5) and the error (9) included in the same address can be updated to the external SDRAM 200 simultaneously as well. Corrected data for errors included in a plurality of codewords that have the same update order are updated to the external SDRAM 200 at the same time, thereby reducing the time required for updating.

The error correction technique according to aspects of the present invention may be recorded in computer-readable media including program instructions to implement various operations embodied by a computer. The media may also include, alone or in combination with the program instructions, data files, data structures, and the like. Examples of computer-readable media include magnetic media such as hard disks, floppy disks, and magnetic tape; optical media such as CD ROM disks and DVD; magneto-optical media such as optical disks; and hardware devices that are specially configured to store and perform program instructions, such as read-only memory (ROM), random access memory (RAM), flash memory, and the like. The media may also be a transmission medium such as optical or metallic lines, wave guides, etc., including a carrier wave transmitting signals specifying the program instructions, data structures, etc. Examples of program instructions include both machine code, such as produced by a compiler, and files containing higher level code that may be executed by the computer using an interpreter. The described hardware devices may be configured to act as one or more software modules in order to perform the operations of the above-described embodiments of the present invention.

As described above, according to aspects of the present invention, corrected data for a plurality of error data are updated to an external SDRAM at the same time, thereby allowing for rapid updating.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An error correction method for use in an optical information storage medium recording and/or reproducing apparatus, in which an error data value is detected from an original data value obtained from an optical information storage medium and stored in an external memory unit and a corrected data value for the error data value is updated to the external memory unit, the error correction method comprising:
receiving position information about positions of a plurality of error data values detected by an error checking and correction (ECC) block and the error data values for a plurality of codewords oriented in a column direction;
comparing the positions of the error data values of the codewords; and
when the plurality of error data values have the same position, updating the external memory unit with corrected data values for the error data values simultaneously using the error data values.

2. The error correction method of claim 1, wherein the comparison of the positions comprises comparing row-direction positions of the error data values of the codewords.

3. The error correction method of claim 2, further comprising, when the error data values compared with each other do not have a same row-direction position, sequentially updating the external memory unit with the corrected data values for the error data values using error values of the error data values.

4. The error correction method of claim 1, wherein the corrected data values are stored at the same address in the external memory unit.

5. The error correction method of claim 1, further comprising the ECC block receiving the original data value stored in the external memory unit and detecting the position information and the error value of the error data value.

6. The error correction method of claim 5, wherein an operation is performed on the original data value and the error value to generate the corrected data values and to update the external memory unit with the corrected data values.

7. An error correction apparatus for use in an optical information storage medium recording and/or reproducing apparatus, the error correction apparatus comprising:
a codeword buffer unit to receive position information about positions of a plurality of error data values detected by an error checking and correction (ECC) block and obtained from an optical information storage medium and to receive error data values for a plurality of codewords oriented in a column direction; and
a control unit to compare the positions of the error data values of the codewords and to update the external memory unit with corrected data values for the error data values using the error data values simultaneously when the plurality of error data values have the same position.

8. The error correction apparatus of claim 7, wherein the control unit compares row-direction positions of the error data values of the codewords.

9. The error correction apparatus of claim 8, wherein when the error data values compared with each other do not have the same row-direction position, corrected data values for the error data values are updated to the external memory unit sequentially using error values of the error data values.

10. The error correction apparatus of claim 7, wherein the control unit comprises a read buffer unit to receive and store the original data value stored in the external memory unit.

11. The error correction apparatus of claim 10, wherein the control unit further comprises:
an error data comparison unit to compare the error data values of the codewords; and
a corrected data generation unit to generate the corrected data value by performing an operation on the original data value and the error value and to update the external memory unit with the corrected data value according to the comparison result of the error data comparison unit.

12. The error correction apparatus of claim 11, wherein the control unit further comprises an address generation unit to set an address of the external memory unit in which the corrected data value is to be stored, using the position information of the error data value and the comparison result of the error data comparison unit.

13. The error correction apparatus of claim 7, wherein the ECC block receives an original data value stored in the external memory unit and detects the position information and the error value of the error data value.

14. An error correction system for use in an optical information storage medium recording and/or reproducing apparatus, the error correction system comprising:
an external memory unit to store an original data value obtained from an optical information storage medium;
an error checking and correction (ECC) block to receive the original data value stored in the external memory unit, to detect an error data value from the original data value, and to generate position information about the position of the error data value to be corrected and an error value of the error corrected value; and
an error update unit to receive position information from the ECC block about positions of a plurality of error data values detected by the ECC block and the error data values for a plurality of codewords oriented in a column direction, to compare positions of the error data values of the codewords, and to update the external memory unit with corrected data values for the error data values using the error data values simultaneously when the plurality of error data values have the same position.

15. The error correction system of claim 14, wherein when the error data values compared with each other do not have the same row-direction position, the error update unit updates the external memory unit with the corrected data values for the error data values sequentially using error values of the error data values.

16. The error correction system of claim 15, wherein an operation is performed on the original data value and the error value to generate the corrected data value and to update the corrected data value to the external memory unit.

17. An error correction method for correcting errors in original data stored on an optical information storage medium, the method comprising:
comparing the positions of a plurality of error data values for a plurality of codewords obtained from an optical information storage medium; and
simultaneously updating an external storage unit with corrected data values using the plurality of error data when the plurality of error data values have the same position.

18. An error correction method for correcting errors in original data stored on an optical information storage medium, the method comprising:
comparing the positions of a plurality of error data values for a plurality of codewords obtained from an optical information storage medium; and
simultaneously generating corrected data values using the plurality of error data when the plurality of error data values have the same position.
